(19) United States
(12) Patent Application Publication
(10) Pub. No.: US 2009/0297731 A1
(43) Pub. Date: Dec. 3, 2009

(54) APPARATUS AND METHOD FOR IMPROVING PRODUCTION THROUGHPUT IN CVD CHAMBER

(75) Inventor: Kamal Kishore Goundar, Yokohama-shi (JP)

Correspondence Address: KNOBBE MARTENS OLSON & BEAR LLP, 2040 MAIN STREET, FOURTEENTH FLOOR, IRVINE, CA, 92614, US

(73) Assignee: ASM JAPAN K.K., Tokyo (JP)

(21) Appl. No.: 12/130,430

(22) Filed: May 30, 2008

(51) Int. Cl. C23C 16/00; H05H 1/24

(52) U.S. Cl. 427/577; 118/723 R; 427/569

(57) ABSTRACT

A plasma CVD apparatus for forming a film on a substrate includes: an evacuatable reaction chamber; capacitively-coupled upper and lower electrodes disposed inside the reaction chamber; and an insulator for inhibiting penetration of a magnetic field of radio frequency generated during substrate processing. The insulator is placed on the bottom surface of the reaction chamber under the lower electrode.

### BACKGROUND OF THE INVENTION

1. Field of the Invention

The present invention relates generally to chemical vapor deposition (CVD chambers and methods for operating CVD chambers, and more specifically, to methods for reducing unwanted deposit accumulation during semiconductor processing and increasing deposition rate in a CVD chamber, which methods consequently improves semiconductor processing throughput.

2. Description of the Related Art

In the manufacturing of semiconductor devices, materials such as carbon and carbon-containing layers are typically deposited on a substrate in a processing chamber. Plasma enhanced chemical vapor deposition (PECVD) methods have been used in the deposition of these carbon-based materials. In accordance with PECVD, a substrate is placed in a vacuum deposition chamber equipped with a pair of parallel plate electrodes.

In a single-substrate processing apparatus, during CVD processing, a film is not only formed on the substrate but also on other regions of the chamber. Unwanted film on these regions produces particles which deposit on the substrate during CVD processing, which as a result deteriorate the quality of the film on subsequent substrates. Thus, the CVD chamber is cleaned periodically by using an in-situ cleaning process. Accumulation of adhesive products on surfaces of electrodes may affect plasma generation or distribution over a substrate and may cause damage to the electrodes. The materials deposited in these areas can affect the deposition rate varying from substrate to substrate and the uniformity of the deposition on the substrate.

Several methods for cleaning CVD chambers have been developed. For example, when fluorine doped SiO₂ and SiN are deposited in a CVD chamber, the inner surface of the chamber can be cleaned by remote plasma cleaning. In that case, argon (Ar) gas is added as a feedstock to stabilize plasma discharge in a remote plasma chamber isolated from the CVD chamber. This technology is disclosed in U.S. Pat. No. 6,187,691, and U.S. Patent Publication No. 2002/0011210A. The following references also disclose chamber cleaning technologies: U.S. Pat. No. 6,374,831; U.S. Pat. No. 6,387,207; U.S. Pat. No. 6,329,297; U.S. Pat. No. 6,271,148; U.S. Pat. No. 6,347,636; U.S. Pat. No. 6,187,691; U.S. Patent Publication No. 2002/0011210A; U.S. Pat. No. 6,352,945; and U.S. Pat. No. 6,383,955. The disclosure of the foregoing references is herein incorporated by reference in their entirety, especially with respect to configurations of a reactor and a remote plasma reactor, and general cleaning conditions.

However, the above conventional methods are not effective in cleaning a carbon-based film; such as amorphous carbon films, including diamond-like carbon films and carbon polymer films, which have high carbon contents.

Furthermore, conventional CVD chambers are constituted primarily by metals such as aluminum, which have high electric conductivity characteristics. Due to the chambers' electrical characteristics, the magnetic field of RF generated during semiconductor processing typically penetrates through the metal, which results in potential loss and consequently degrades the overall process performance, including system throughput.

### SUMMARY OF THE INVENTION

During the process of depositing a carbon-based film on sequential substrates a determinable number of times, a carbon-based film is also deposited on areas other than the substrate, such as an inner wall and a showerhead (an upper electrode). Upon completion of deposition of a carbon-based film on a substrate, the cleaning of the reactor is initiated. If an oxygen-containing gas or oxygen-based gas is used as a cleaning gas, because oxygen ions are negatively charged, a plasma sheath is formed on a cleaning target by oxygen plasma generation, inhibiting oxygen ions from reaching the cleaning target. Further, because the life of oxygen ions is short, they cannot reach locations in the reactor far from the place where oxygen ions are generated, resulting in insufficient cleaning at the locations. On the other hand, known remote plasma cleaning techniques are time consuming processes. Remote plasma units typically provide reactive species, such as a free radicals, at a flow rate and an intensity that do not result in level of free radicals sufficient to provide reliable cleaning efficiency. As a result, contaminant particles are generated and accumulate on the inner wall and/or the showerhead, and then fall on a substrate surface during deposition processes.

Furthermore, conventional CVD chambers are primarily designed from metals, such as aluminum, which have high electric conductivity characteristics. Due to these electrical characteristics, the RF magnetic field in plasma generated by applying a potential to the showerhead from an RF potential source typically penetrates through the metal, which results in the potential loss during processing and consequently degrading the overall process performance including the system throughput.

In addition, due to the penetration of the RF magnetic field, large amounts of unwanted deposits are accumulated at the bottom of the chamber. To remove these deposits using either with in-situ or remote cleaning methodology requires several minutes or hours. As a result, the throughput of the system is tremendously degraded.

In an aspect, the disclosed embodiments wherein one or more of the problems can be solved include a plasma CVD apparatus for forming a film on a substrate comprising:
an evacuatable reaction chamber;
capacitively-coupled upper and lower electrodes disposed inside the reaction chamber, wherein a substrate is to be placed on the lower electrode, said reaction chamber having a metal bottom surface above which the lower electrode is installed; and
an insulator for inhibiting penetration of a radio frequency (RF) magnetic field generated during substrate processing, said insulator being placed on the bottom surface of the reaction chamber under the lower electrode.

In an embodiment, the insulator can effectively inhibit penetration of a magnetic field so that a plasma can be confined to the reaction region between the upper and lower electrodes, thereby surprisingly increasing a deposition rate and surprisingly decreasing unwanted deposition inside the reaction chamber. In an embodiment, “inhibiting” means partially or substantially suppressing penetration of a magnetic field therethrough to the extent that one or more of the intended objectives are realized. The material, shape, and dimensions of the insulator can be selected to be adapted to the particular configurations of the reaction chamber in use and achieve one or more of the intended objectives.

In any of the foregoing embodiments, the upper electrode may be a showerhead, and the lower electrode may be a susceptor, which may be composed of a top plate and a heating plate. The showerhead and the susceptor are disposed parallel to and facing each other. The reaction chamber may be made of a metal, and the bottom surface is constituted by a metal such as aluminum. The showerhead and the susceptor are insulated from each other, and the susceptor is typically grounded and insulated from the reaction chamber. However, the insulator may exclude an electric insulator for insulating the susceptor from the reaction chamber. Further, in an embodiment, the insulator may be disposed solely on the bottom surface of the reaction chamber, and in another embodiment, an additional insulator (e.g., ring-shaped) may be disposed outside and around the first insulator in a wafer transferring region of the reaction chamber, which may be separated into two portions composed of a reaction region and the wafer transferring region, between which the susceptor moves. In an embodiment, the insulator may be disposed only in the wafer transferring region.

In any of the foregoing embodiments, the insulator may be made of a ceramic material. In an embodiment, the ceramic material may be selected from the group consisting of aluminum oxide, aluminum nitride, silicon oxide, and silicon carbide. In an embodiment, the insulator may have a coating or may be constituted by multiple layers.

In any of the foregoing embodiments, the diameter of the insulator may be 80% to 120% (including 90%, 100%, 110%, and values between any two numbers of the foregoing) of the diameter of the lower electrode, and in an embodiment, the insulator may have a diameter larger than that of the lower electrode. For example, the diameter of the insulator may be in the range of 300 mm to 450 mm, preferably 350 mm to 400 mm. In any of the foregoing embodiments, the insulator may have a thickness greater than a distance between the upper and lower electrodes set for plasma processing. In an embodiment, the insulator may have a thickness of 1 mm to 60 mm, preferably 5 mm to 30 mm (typically at least 5 mm). In an embodiment, the insulator may cover 50% to 100% (including 60%, 70%, 80%, 90%, and values between any two numbers of the foregoing) of the bottom surface as viewed from above.

In any of the foregoing embodiments, the insulator may be mechanically replaceable. In an embodiment, the insulator may be fastened to the bottom surface with screws.

In any of the foregoing embodiment, the lower electrode may be supported at its center by a support, and the bottom surface of the reaction chamber may have a hole through which the support is installed, wherein the insulator may have a ring shape having a hole corresponding to the hole of the bottom surface. In an embodiment, the insulator may further have holes through which wafer lift pins are inserted or in which wafer lift pins are fitted. In any of the foregoing embodiments, the insulator may have a shape and size corresponding to a shape and size of the bottom surface.

In another aspect, the disclosed embodiments wherein one or more of the problems can be solved include a method for improving production throughput in a plasma CVD apparatus comprising: an evacuatable reaction chamber; capacitively-coupled upper and lower electrodes disposed inside the reaction chamber; and an electrical insulator placed on the bottom surface of the reaction chamber under the lower electrode, said method comprising:
installing an insulator, for inhibiting penetration of a magnetic field generated by application of radio frequency (RF) power to the upper and lower electrodes, under the lower electrode and on a metal bottom surface of the reaction chamber; and
depositing a film on a substrate placed on the lower electrode by plasma CVD applying RF power between the upper and lower electrodes, wherein as a result of the installed insulator, a deposition rate is increased and unwanted deposition inside the reaction chamber is reduced.

In the above, the insulator may be made of a ceramic material, and any embodiment of the disclosed apparatuses can be applied to any embodiment of the disclosed methods.

In any of the foregoing embodiment, the deposition rate may be increased by at least 10% (including 15%, 20%, 25%, and values between any two numbers of the foregoing) as compared with that without the insulator. Due to the insulator, the deposition rate can be surprisingly increased.

In any of the foregoing embodiments, the method may further comprise cleaning the reaction chamber, wherein a frequency of the cleaning is reduced as a result of the installed insulator. In an embodiment, the frequency of the cleaning may be reduced by at least 50% (including 70%, 90%, and values between the foregoing) as compared with that without the insulator. That is, in an embodiment, the length of a cleaning cycle can be extended two-fold to ten-fold. It is quite surprising and unexpected that due to the insulator, no unwanted deposits can be observed while a large number of wafers can be processed between cleanings that have a large effect on throughput, such as ex situ we chamber cleaning.

In any of the foregoing embodiments, the cleaning may be conducted using a fluorine-containing gas. In an embodiment, an oxygen-containing gas, a hydrogen-containing gas, and/or a nitrogen-containing gas may be used in addition to or instead of the fluorine-containing gas.

In any of the foregoing embodiments, the film may be a carbon-based film, such as an amorphous carbon film, a diamond-like carbon film, a carbon polymer film, etc. In another embodiment, the film may be a silicon carbide film, a silicon nitride film, or a siloxane polymer film.

For purposes of summarizing aspects of the invention and the advantages achieved over the related art, certain objects and advantages of the invention are described in this disclosure. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

Further aspects, features and advantages of this invention will become apparent from the detailed description of the preferred embodiments which follow.

### BRIEF DESCRIPTION OF THE DRAWINGS

These and other features of this invention will now be described with reference to the drawings of preferred embodiments which are intended to illustrate and not to limit the invention. The drawings are oversimplified for illustrative purposes and are not to scale.

FIG. 1 is a schematic diagram showing an example of a plasma CVD apparatus for forming a polymer hard mask provided with a ceramic material positioned at the bottom surface of the reactor interior according to an embodiment of the present invention.

FIG. 2 is a schematic diagram showing an example of a plasma CVD apparatus provided with a ceramic material positioned at the bottom surface of the reactor interior according to an embodiment of the present invention.

FIG. 3 is a graph showing the deposition rate of a polymer hard mask material processed according to an embodiment of the present invention (Example 1 and Comparative Example 1).

FIG. 4 is a graph showing the film thickness of unwanted deposits according to an embodiment of the present invention (Example 2 and Comparative Example 2).

FIG. 5 is a graph showing the relationship between the number of wafers processed and particle counts according to embodiments of the present invention.

### DETAILED DESCRIPTION OF THE PREFERRED EMBODIMENTS

The present invention will be explained in detail with reference to preferred embodiments. However, the preferred embodiments are not intended to limit the present invention.

In an aspect, the disclosed embodiments include a method of continuously forming carbon-based films on substrates, comprising: (i) providing an insulator, typically a ceramic material, at the bottom surface of the chamber interior below the heater top surface and adjacent to the bottom aluminum surface, (ii) forming a carbon-based film on a substrate in a reactor a pre-selected number of times; (iii) exciting oxygen gas, and fluorine-containing gas, and inert gas to generate a plasma for cleaning; (iv) cleaning an inside of the reactor with the plasma to remove particles accumulated during step (ii) on the inside of the reactor.

The above aspect includes, but is not limited to, the following embodiments:

In any of the foregoing embodiments, the ceramic material in step (i) can be an oxide including aluminum. Furthermore, the ceramic material in the step (i) has a thickness of above 0.1 mm.

In any of the foregoing embodiments, the ceramic material in step (i) can be positioned between the heater and the reactor bottom. The ceramic material can be positioned in contact to the bottom surface of the reactor.

In any of the foregoing embodiments, the ceramic material in step (i) can be positioned between the heater and the reactor bottom, where a contact portion of the ceramic in contact with the bottom surface of the reactor can be less than 50% of the area of the ceramic material, whereas the other 50% or more of the ceramic is a non-contact portion that is spaced apart from the bottom surface of the reactor.

In any of the foregoing embodiments, the ceramic material in step (i) has a spacing (a gap between the ceramic material and the bottom surface in the non-contacting portion) of greater than 0.1 mm and less than the thickness of the ceramic material itself.

In any of the foregoing embodiments, step (iii) may be conducted in situ in the reactor or may be conducted in the reactor and in a remote plasma unit. The method may further comprise determining a priority area of cleaning inside the reactor prior to step (iii). Step (iv) may comprise controlling pressure inside the reactor according to the priority area of cleaning.

In any of the foregoing embodiments, the method may further comprise selecting a cleaning gas including the oxygen gas, a nitrogen fluoride gas as the fluorine-containing gas, and an inert gas such as argon. Step (iii) may further compromise controlling a gap between and upper electrode and a lower electrode. Step (iv) may comprise controlling gap between the electrodes at about 10 mm to about 35 mm. In the above the oxygen gas may be O₂ gas and the inert gas can be argon. The fluorine containing gas is preferably nitrogen tri-fluoride.

In any of the foregoing embodiments, the carbon-based polymer film in step (ii) may be a carbon polymer film formed by: (a) vaporizing a hydrocarbon-containing liquid monomer (C_{α}H_{β}X_{γ}, wherein α and β are natural numbers of 5 or more; γ is an integer including zero; X is O, N or F) having a boiling point of about 20° C. to about 350° C. and which has no benzene structure; (b) introducing said vaporized gas into a CVD reaction chamber inside which a substrate is placed; and (c) forming a hydrocarbon-containing polymer film on said substrate by plasma polymerization of said gas.

In another aspect, the disclosed embodiments include a method of self-cleaning a plasma reactor using a cleaning gas containing oxygen gas, nitrogen tri-fluoride and inert gas at a suitable pre-selected pressure upon depositing a carbon-based film on a substrate a determinable number of times, comprising: changing the cleaning gas and/or the pressure; the step of changing the cleaning gas comprising: increasing a flow rate of oxygen gas for increasing a ratio of an etching rate of a carbon polymer accumulated in the reactor.

The method may further comprise selecting a cleaning gas including the oxygen gas, fluorine-containing gas, and an inert gas such as argon. Step (i) may further compromise controlling a gap between and upper electrode and a lower electrode. Step (i) may comprise controlling a gap between the electrodes at about 10 mm to about 35 mm. In the above, the oxygen gas may be O₂ gas and the inert gas can be argon. The fluorine-containing gas may be nitrogen tri-fluoride.

In any of the aforesaid embodiments, in step (i), the oxygen gas and the fluorine based gas may be used. The oxygen gas may be O₂ gas, and in other embodiments, may be an oxygen-containing or oxygen-based gas such as CO₂, CO, O₃, or N₂O, or a mixture any of the foregoing. In any of the aforesaid embodiments, the inert gas may be any one or more of Ar gas, He gas, Ne gas, Kr gas, and Xe gas.

In any of the aforesaid embodiments, in step (ii), a flow rate of the oxygen gas may be set at 100 to 5,000 sccm (including 1,000 sccm, 2,000 sccm, 3,000 sccm, and values between any two numbers of the foregoing), a flow rate of the inert gas may be set at 1,000 to 10,000 sccm (including 3,000 sccm, 4,000 sccm, 5,000 sccm, and values between any two numbers of the foregoing), rate of the fluorine gas may be set at 10 to 500 sccm (including 25 sccm, 50 sccm, 100 sccm, 200 sccm, 300 sccm, and values between any two numbers of the foregoing) in embodiments.

In embodiments, the flow rate ratio of (fluorine gas)/(oxygen gas)/(inert gas) may be (1-50)/(100)/(0-1000), preferably (3-15)/(100)/(70-700). In embodiments, a flow rate of the oxygen gas may be set at a value which is 10% to 60% of total flow gas flow rates of the inert gas, the oxygen gas, and fluorine-containing gas. Furthermore, in embodiments, a flow rate of the fluorine gas may be set at a value which is 0.5% to 10% of total flow gas flow rates of the inert gas, the oxygen gas, and fluorine-containing gas.

In any of the aforesaid embodiments, in steps (i) to (ii), a susceptor or substrate support on which the substrate is placed may be controlled at a temperature of 200° C. or higher (e.g., 340° C. or higher).

In any of the aforesaid embodiments, the carbon-based polymer film may be a carbon polymer film formed by: (I) vaporizing a hydrocarbon-containing liquid monomer (C_{α}H_{β}X_{γ}, wherein α and β are natural numbers of 5 or more; γ is an integer including zero; X is O, N or F) having a boiling point of about 20° C. to about 350° C. which is not substituted by a vinyl group or an acetylene group; (II) introducing said vaporized gas into a CVD reaction chamber inside which a substrate is placed; and (III) forming a hydrocarbon-containing polymer film on said substrate by plasma polymerization of said gas. In an embodiment, the liquid monomer technology disclosed in U.S. Patent publication No. 2006/0084280 and No. 2007/0218705 can be used, the disclosure of which is herein incorporated by reference in their entirety for purposes of teaching suitable plasma polymerization methods for depositing films.

In the present disclosure including the above, the ranges described may include or exclude the endpoints in embodiments.

An embodiment of the present invention provides a method of self-cleaning a plasma reactor using a cleaning gas containing oxygen gas, fluorine based gas, and inert gas upon depositing a carbon-based film sequentially on a plurality of substrates. In an embodiment, the cleaning of the reactor can be conducted every after a given number of substrates (e.g., after depositing on 1-50 substrates, typically 4-25 substrates) are processed. The frequency of cleaning can be determined depending on the amount of unwanted film accumulated inside the reactor during the deposition process, the amount of particles generated by the cleaning itself, etc. The number of substrates between cleaning steps can be pre-selected based upon experimentation, or can be determined on the fly through feedback of wall deposit measurements.

In another embodiment a method of operating a CVD tool comprises: (i) introducing inert gas to a remote plasma unit, followed by igniting plasma; (ii) upon the ignition, introducing oxygen gas together with inert gas and flowed by the fluorine-based gas to the remote plasma unit; (iii) exciting the oxygen and fluorine gas together with the inert gas via plasma in the remote plasma unit; (iv) introducing the excited inert gas and the oxygen and fluorine gas to the reactor, thereby performing self-cleaning of the reactor. The type and the flow rate of the rare gas and the oxygen gas can be those described earlier or anywhere in the present disclosure.

The present invention will be described in detail with reference to other embodiments. The present invention, however, is not limited to these embodiments. Additionally, a requirement in an embodiment is freely applicable to other embodiments, and requirements are mutually replaceable unless special conditions are attached.

The reactor may be a capacitively-coupled plasma apparatus wherein a showerhead can serve as an upper electrode and a susceptor, which serves as a substrate support and lower electrode, is disposed in parallel to the upper electrode. The reactor may be a PECVD apparatus, HDP-CVD apparatus, ALD apparatus, etc. in which unwanted particles are accumulated on the showerhead and the inner wall during deposition of the film of interest on a substrate.

The film deposited on a substrate in the reactor, the deposition of which also calls for periodic cleaning inside the reactor of the present invention, is a carbon-based film which may be defined as a film containing 30% or more carbon (typically 30% to 80%, preferably 40% to 60%) per mass of the entire compositions in an embodiment. In another embodiment, the carbon-based film may be defined as a film formed with a carbon skeleton. In another embodiment, the carbon-based film may be defined as a film having a general formula CₓH_{y} (x, y are an integer of 2 or greater). The carbon-based film includes, but is not limited to, a nano-carbon polymer film as disclosed in U.S. Patent Publication No. 2006/0084280 and No. 2007/0218705 (the disclosure of which is herein incorporated by reference for the purpose of describing suitable deposition processes and films), and an amorphous carbon film (including diamond-like carbon film) disclosed in U.S. Patent Publications No. 2003/0091938 and No. 2005/0112509, U.S. Pat. No. 5,470,661, and U.S. Pat. No. 6,428,894 (the disclosure of which is herein incorporated by reference for the purpose of describing suitable deposition processes and films).

For example, as disclosed in U.S. Patent Publication No. 2006/0084280 mentioned above, a nano-carbon polymer film can be formed a method which comprises the steps of vaporizing a hydrocarbon-containing liquid monomer (C_{α}H_{β}X_{γ}, wherein α and β are natural numbers of 5 or more; γ is an integer including zero; X is O or N) having a boiling point of 20° C.-350° C. which is not substituted by a vinyl group or an acetylene group, introducing the vaporized gas into a CVD reaction chamber inside which a substrate is placed, and forming a hydrocarbon-containing polymer film on the substrate by plasma polymerizing the gas. The substrate is, for example, a semiconductor device substrate. In the above method, the liquid monomer may be introduced into a heater disposed upstream of the reaction chamber and vaporized. Additionally, the liquid monomer may be flow-controlled by a valve upstream of the heater, and introduction of the liquid monomer into the heater may be blocked by a shutoff valve disposed between the flow control valve and the heater and kept at 80° C. or lower or at a temperature lower than that of heating/vaporization by approximately 50° C. or more except when a film is formed. Or, the liquid monomer may be flow-controlled by a valve disposed upstream of the heater and kept at 80° C. or lower or at a temperature lower than that of heating/vaporization by approximately 50° C. or more, and at the same time introduction of the liquid monomer into the heater may be blocked except when a film is formed.

Further, as disclosed in U.S. Patent Publication No. 2006/0084280, usable liquid organic monomers for a nano-carbon polymer film include the following:

As a liquid organic monomer, cyclic hydrocarbon can be used. The cyclic hydrocarbon may be substituted or non-substituted benzene. Further, the substituted or non-substituted benzene may be C₆H₆₋ₙRₙ (wherein n, 0, 1, 2, 3); R may be independently —CH₃ or —C₂H₅. The liquid monomer may be a combination of two types or more of substituted or non-substituted benzene. In the above, the substituted benzene may be any one or more of 1,3,5-trimethylbenzene, o-xylene, m-xylene or p-xylene; in addition to a benzene derivative, the cyclic hydrocarbon may be any one or more of cyclohexane, cyclohexene, cyclohexadiene, cyclooctatetraene, cyclopentane, and cyclopentene. The liquid monomer may be linear hydrocarbon, and the linear hydrocarbon may also be any one or more of pentane, iso-pentane, neo-pentane, hexane, 1-pentene, 1-hexene, 1-pentyne, and isoprene.

As a specific example, C₆H₃(CH₃)₃ (1,3,5-trimethylbenzene (TMB); boiling point of 165° C.) or C₆H₄(CH₃)₂ (dimethylbenzene(xylene); boiling point of 144° C.) can be mentioned. In addition to the above, a linear alkane (CₙH₂₍ₙ₊₁₎), pentane (boiling point of 36.1° C.), iso-pentane (boiling point of 27.9° C.) or neo-pentane (boiling point of 9.5° C.), wherein n is 5, or hexane (boiling point: 68.7° C.) or isoprene (boiling point: 34° C.), wherein n is 6, can be used singly or in any combination as a source gas.

Additionally, a liquid organic monomer can be a hydrocarbon-containing liquid monomer (C_{α}H_{β}X_{γ}, wherein α and β are natural numbers of 5 or more; γ is an integer including zero; X is O, N or F) having a boiling point of room temperature or higher (e.g., approximately 20° C.-approximately 350° C.). Using this monomer, a hard mask can be formed. Preferably, the carbon number is 6-30; the carbon number is 6-12. In this case as well, the liquid monomer can be cyclic hydrocarbon, and the cyclic hydrocarbon may also be substituted or non-substituted benzene. Further, the substituted benzene or the non-substituted benzene may be C₆H₆₋ₙRₙ (wherein n is 0, 1, 2, or 3); R may be independently —CH₃, —C₂H₅, or —CH═CH₂. Additionally, the liquid monomer can be a combination of two types or more of the non-substituted benzene.

In the above, the substituted benzene may be any one of 1,3,5-trimethylbenzene, o-xylene, m-xylene, or p-xylene. In addition to benzene derivatives, the cyclic hydrocarbon may be any one of cyclohexene, cyclohexadiene, cyclooctatetraene. Additionally, it may be linear hydrocarbon; the linear hydrocarbon may be pentane, iso-pentane, neo-pentane, hexane, 1-pentene, 1-hexene, 1-pentyne, and/or isoprene.

Additionally, a reaction gas composed of only the liquid monomer may be used. Specifically, C₆H₅(CH═CH₂) (vinylbenzene (styrene); boiling point of 145° C.) can be mentioned. In addition to this, as liner alkene (CₙHₙ (n=5)), 1-pentene (boiling point of 30.0° C.); or as liner alkyne (CₙH₂₍ₙ₋₁₎ (n=5), 1-pentyne (boiling point of 40.2° C.), etc. can be used singly or in any combination as a source gas.

In the preferred embodiments, the cleaning of the reactor can include remote plasma cleaning. General methods of chamber cleaning are disclosed in U.S. Pat. No. 6,187,691, U.S. Patent Publication No. 2002/0011210A, U.S. Pat. No. 6,374,831, U.S. Pat. No. 6,387,207, U.S. Pat. No. 6,329,297, U.S. Pat. No. 6,271,148, U.S. Pat. No. 6,347,636, U.S. Pat. No. 6,187,691, U.S. Patent Publication No. 2002/0011210A, U.S. Pat. No. 6,352,945, and U.S. Pat. No. 6,383,955, for example, the disclosures of which are herein incorporated by reference for the purpose of describing suitable remote plasma cleaning apparatus and methods.

During the process of depositing a carbon-based film on a substrate a pre-selected number of times, a carbon-based film is also deposited on areas other than the substrate, such as an inner wall and a showerhead (an upper electrode). Upon completion of deposition of a carbon-based film on a substrate, the cleaning of the reactor is initiated.

If an oxygen-containing gas or oxygen-based gas is used as a cleaning gas, because oxygen ions are negatively charged, a plasma sheath is formed on a cleaning target by oxygen plasma generation, inhibiting oxygen ions from reaching the cleaning target. Further, because the life of oxygen ions is short, they cannot reach locations in the reactor far from the place where oxygen ions are generated, resulting in insufficient cleaning at such remote locations. On the other hand, known remote plasma cleaning is a time consuming process. A remote plasma unit typically provides reactive species, such as free radicals, at a flow rate and an intensity that do not result in level of free radicals sufficient to provide a reliable cleaning efficiency. As a result, contaminant particles are generated and accumulate on an inner wall or the showerhead, and then fall on a substrate surface during a deposition process. Furthermore, if a fluorine-containing gas such as NF₃, C₂F₆, and/or C₃F₈, is used as a cleaning gas in a conventional manner, fluorine binds to hydrogen present in the carbon-based film during a cleaning process, thereby generating HF which is likely to cause erosion to a showerhead or susceptor made of aluminum or its alloy. Consequently, contaminant particles are generated and accumulate on an inner wall or the showerhead, and then fall on a embodiments, a flow rate of the fluorine gas may be set at a value which is 0.5% to 10% of total flow gas flow rates of the rare inert gas, the oxygen gas, and fluorine-based gas.

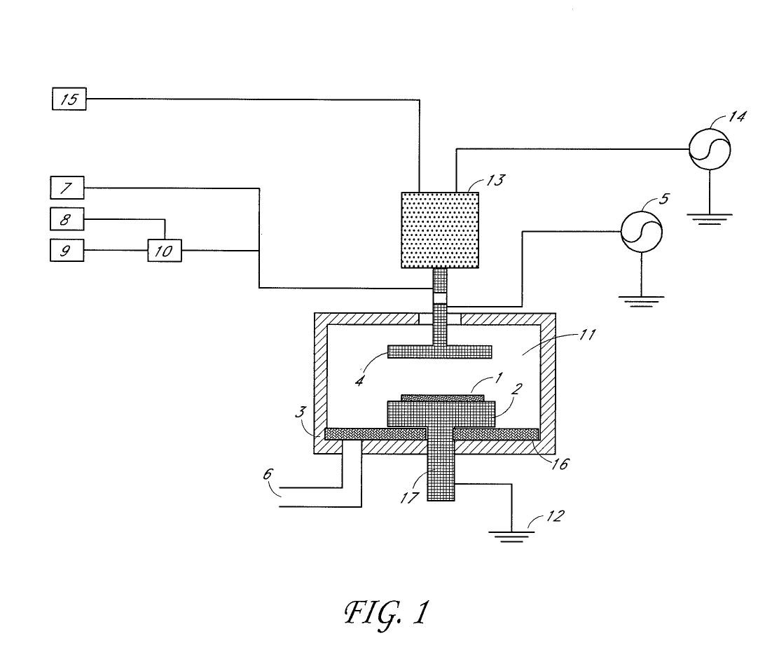

FIG. 1 is a schematic diagram of an apparatus combining a vaporizer and a plasma CVD reactor, which can be used in an embodiment of the present invention. This figure is not to scale and excessively simplified for illustrative purposes. An insulating member in the form of a ceramic material 16 is located/added to the bottom surface of the reaction chamber 11 inside the interior 3 in accordance with an embodiment of the present invention. An apparatus which can be used in the present invention is not limited to the example shown in FIG. 1. In FIG. 1, the ceramic material 16 is confined to the bottom surface of the reaction chamber 11, whereas the upper and side walls of the chamber have exposed metal, without insulating cover.

In this example, by providing a pair of electrically conductive flat-plate electrodes 4, 2 in parallel and facing each other inside a reaction chamber 11, applying RF power 5 to one side, and electrically grounding 12 the other side, plasma is excited between the electrodes4, 2. In the illustrated embodiment, a temperature regulator is provided in a lower stage 2 which is supported by a pedestal or support 17, and a temperature is kept constantly at a given temperature in the range of 0° C.-650° C. to regulate a temperature of a substrate 1 placed thereon. An upper electrode 4 serves as a shower plate as well, and reaction gas is introduced into the reaction chamber 11 through the shower plate. Additionally, in the reaction chamber 11, an exhaust pipe 6 is provided through which gas inside the reaction chamber 11 is exhausted.

A vaporizer 10 which vaporizes a liquid organic monomer (a precursor for plasma CVD in the methods described herein) has an inlet port for a liquid and an inlet port for an inert gas in an embodiment and comprises a mixing unit for mixing these gases and a unit for heating the mixture. In the embodiment shown in FIG. 1, an inert gas is introduced from an inert gas flow-controller 8 to the vaporizer 10; and a liquid monomer is introduced from a liquid monomer flow-controller 9 into the vaporizer 10. A heating temperature of the liquid monomer flow-controller 9 and the liquid source piping between the liquid monomer flow-controller 9 and the vaporizer 10 is determined based on characteristics of a liquid source; the temperature is kept in the range of 0° C.-350° C. in this embodiment. A heating temperature of a vaporizer 10 is also determined based on characteristics of a liquid source; the temperature is kept in the range of 0° C.-350° C. in this embodiment. In an embodiment, the liquid monomer includes a polymeric liquid. In that case, the temperature should be kept low. Vaporized gas is introduced into the reactor through gas piping. Additionally, the embodiment shown in FIG. 1 is designed to be able to introduce an additive gas from a gas flow-controller 7 into the reactor. Additionally, an inert gas can also be introduced into the reactor without passing through the vaporizer 10. The number of the gas flow-controller 7 is not limited to one, but can be provided appropriately to meet the number of gas types used.

In one embodiment, the piping introducing the gas from the vaporizer to the reactor and a showerhead unit in an upper portion of the reactor are heated/temperature-controlled at a given temperature in the range of 30° C.-350° C. by a heater and their outer side is covered by an insulating material.

The apparatus shown in FIG. 1 is provided with a remote plasma unit 13 to which given gas species are supplied a given flow rate from a gas flow mass control unit 15. RF power is applied to the remote plasma unit from a remote plasma power source 14, thereby igniting plasma and generating plasma for cleaning. Generated plasma and radicals are introduced to the reaction chamber 11 via an upper part, thereby conducting cleaning of the reactor. In an embodiment, more than one gas flow mass control unit 15 can be used and suitably arranged depending on the type of gas, etc.

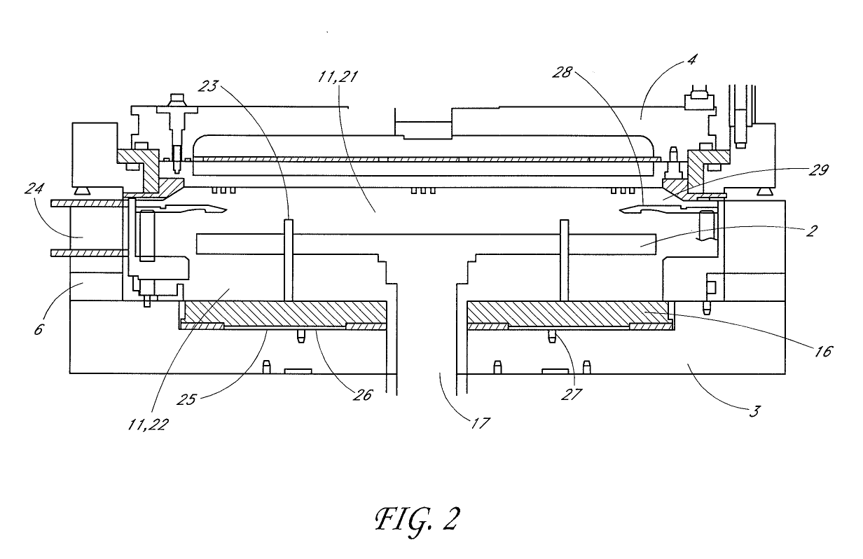

FIG. 2 is a more detailed schematic diagram of the plasma CVD apparatus according to an embodiment of the present invention. However, like FIG. 1, this figure is not to scale and simplified for illustrative purposes.

In this figure, an insulating cover or member in the form of a ceramic plate 16 is disposed on a bottom surface 25 and fastened by screws 27. Any suitable fastening means including press-fit and latching members can be used. A portion 26 of the rear surface of the ceramic plate 16 is not in contact with the bottom surface 25. The ceramic plate 16 is shaped corresponding to the configuration of the bottom surface 25. In the center, the bottom surface 25 and the ceramic plate 16 have a through-hole in which a support 17 of a susceptor 2 is arranged. Thus, the ceramic plate 16 is ring-shaped. Wafer lift pins 23 extend from the ceramic plate 16. The ceramic plate 16 may have holes for the lift pins 23 through which the substrate surface during a deposition process. The above theories are not intended to limit the present invention.

In an embodiment of the present invention, a carbon-based film can effectively be removed using high concentration oxygen gas and low flow fluorine based gas incorporating with inert gas. When using a high ratio oxygen gas and low flow fluorine gas as a cleaning gas, C and H in the carbon-based film (e.g., C:H=50%:50%) react with O and F that generate CO₂, COF2 and H₂O, which are discharged from the reactor to an exhaust system. These species are not likely to cause erosion to electrodes, thereby effectively suppressing generation of contaminant particles.

When oxygen gas is added to fluorine gas, a plasma can be more stabilized and distributed widely inside the reactor, thereby more uniformly supplying an etchant (etching agent) to a wide area of the reactor. As a result, it is possible to increase a cleaning rate without causing damage to the electrodes. A ratio of oxygen gas to fluorine gas may be 100:0 to 0:100 including 100:20, 100:10, 100:5, 100:2.5, and ranges between any two numerals of the foregoing. In general low flow of fluorine is preferable for higher cleaning efficiency. However, the ratio can be selected depending on a priority or target area of cleaning in the cleaning process. If priority is given to electrodes for cleaning, the ratio may be set high, and if priority is given to an inner wall of the reactor, the ratio may be set low. For example, if the deposition temperature is relatively low, accumulation of more particles on the electrodes and the inner wall of the reactor occurs, and if the deposition temperature is relatively high, accumulation of less particles occurs. It is possible to determine in advance through experiments which section of the reactor needs to be targeted more than other sections for cleaning.

In the above embodiments and embodiment described below, the oxygen gas is preferably O₂ gas. Fluorine-containing etchant source gas is preferably nitrogen tri-fluoride.

In embodiments, the flow rate ratio of (fluorine gas)/(oxygen gas)/(inert gas) may be (100)/(1-100)/(0-100), preferably (100)/(20-50)/(0.1-25). In embodiments, a flow rate of the oxygen gas may be set at a value which is 10% to 60% of total flow gas flow rates of the rare inert gas, the oxygen gas, and fluorine-based gas. Furthermore, in lift pins 23 are inserted, or the lift pins 23 are fixedly secured to the ceramic plate 16. The interior of this reaction chamber 11 is divided into two regions: a reaction region 21 and a wafer transferring region 22. When the susceptor 2 moves up, the periphery of the susceptor 2 comes in contact with an edge exclusion member 28 and separates the interior 11 into the reaction region 21 and the wafer transferring region 22. The ceramic plate 16 is disposed in the wafer transferring region 22. In the reaction region 21, an exhaust port 29 is provided, and in the wafer transferring region 22, a wafer in/out port 24 and an exhaust port 6 are provided. In the wafer transferring region 22, an additional ceramic plate can be arranged along side walls around the susceptor 2. In this figure, the bottom surface 25 is fully covered by the ceramic plate 16 as viewed from above, and the diameter of the ceramic plate 16 is larger than that of the susceptor 2 and substantially or nearly the same as that of the showerhead 4. Further, in this figure, the ceramic plate 16 is arranged substantially in parallel to the susceptor 2 and also to the showerhead 4. The thickness of the ceramic plate 16 is determined in order to effectively block penetration of the magnetic field of radio frequency generated during wafer processing, thereby effectively confining the magnetic field to the reaction region. As a result, surprisingly, the deposition rate can be increased and accumulation of unwanted deposits can virtually be inhibited. While not drawn to scale, it is apparent from FIG. 2 that in the illustrated example the thickness of the ceramic plate 16 is greater than the electrode spacing when the susceptor 2 is raised into the processing position. No insulating member of equivalent thickness is positioned in the reaction region 21 in the illustrated example.

In the present disclosure where conditions and/or structures are not specified, the skilled artisan in the art can readily provide such conditions and/or structures, in view of the present disclosure, as a matter of routine experimentation. Further, the disclosure of U.S. Patent Publication No. 2007/0248767 can be used in embodiments of the present invention, the disclosure of which is herein incorporated by reference for the purpose of describing suitable deposition conditions for carbon-based film.

The present invention will be explained with reference to preferred embodiment and drawings. The preferred embodiments and drawings are not intended to limit the present invention. Also, in the present disclosure, the numerical numbers applied in embodiments can be modified in other embodiments (e.g., within a range of ±50% relative to the illustrated embodiments), and the ranges applied in embodiments may include or exclude the endpoints.

### EXAMPLE 1 AND COMPARATIVE EXAMPLE 1

Deposition conditions: Deposition conditions in the examples were as follows: Eagle®12 (ASM Japan) possessing a basic structure shown in FIGS. 1 and 2 was used as a reactor. Additionally, in the case of these examples, although a liquid monomer was flow-controlled by a flow control unit in a liquid phase, an amount of gas introduced into a reactor was obtained by molar conversion from the flow rate of the liquid.

### COMPARATIVE EXAMPLE 1

Reactor settings:

Temperature of upper electrode (shower plate): 180° C.

Size of shower plate: φ325 mm (Size of substrate: φ300 mm)

Susceptor temperature: 340° C.

Vaporizer: Vaporizing unit temperature: 40° C.

Controlled temperature of gas inlet piping: 100° C.

Gap between shower plate and susceptor: 16 mm

Process conditions:

Precursor: Cyclopentene: 200 sccm

He supplied to vaporizer: 500 sccm

Ar supplied to the reactor: 1700 sccm

Process gas He supplied to the reactor: 1300 sccm

RF Power (13.56 MHz): 2300 W

Pressure: 733 Pa

Deposition time: 18.5 sec

Deposited film properties:

Deposition Rate: 640 nm/min

Thickness: 200 nm

Reflective Index (n) @633 nm: 1.88

Extinction Coefficient (k) @633 nm: 0.08

Stress: −286 MPa

### EXAMPLE 1

Under the substantially same conditions as in Comparative Example 1 except that a ceramic material was located at the bottom surface of the chamber interior below the heater top surface and adjacent to the bottom aluminum surface.

A deposition rate was evaluated in the same way as in Comparative Example 1.

Ceramic material:

The diameter of the ceramic material: 360 mm

The thickness of the ceramic material: 26 mm

The material of the ceramic material: Al₂O₃

The diameter of the susceptor: 340 mm

The diameter of the shower head: 350 mm

Process conditions:

Precursor: Cyclopentene: 200 sccm

He supplied to vaporizer: 500 sccm

Ar supplied to the reactor: 1700 sccm

Process gas He supplied to the reactor: 1300 sccm

RF Power (13.56 MHz): 2300 W

Pressure: 733 Pa

Deposition time: 15.5 sec

Deposited film properties:

Deposition Rate: 790 nm/min

Thickness: 200 nm

Reflective Index (n) @633 nm: 1.88

Extinction Coefficient (k) @633 nm: 0.09

Stress: −288 MPa

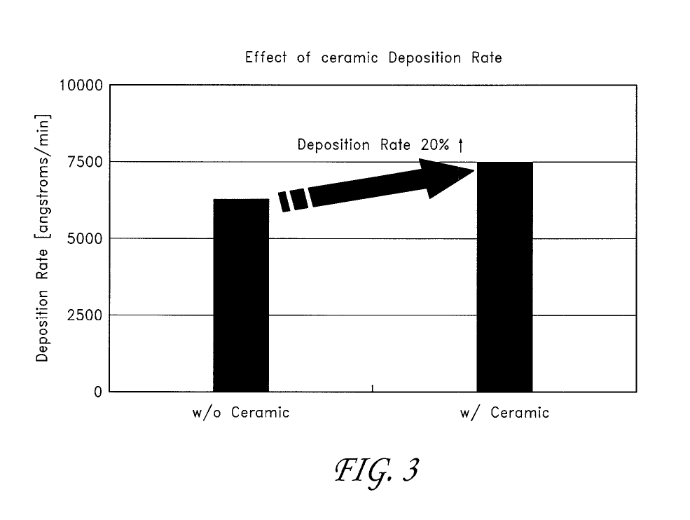

As compared with Comparative Example 1, when the ceramic material was located at the bottom surface of the chamber interior below the heater top surface and adjacent to the bottom aluminum surface, surprisingly, the deposition rate was increased by more than 10%, and in the conducted experiments the rate increased by more than 15%, specifically approximately 20% as shown in FIG. 3.

During the process of film formation, some of the molecules come in contact with the chamber body, such as aluminum walls and aluminum reactor bottom surface resulting in the accumulation of the unwanted deposits and degrading the process performance and potential loss. Therefore it is desirable to develop a methodology that can minimize the amount of molecules in contact to the areas of the chamber and remove the unwanted residues accumulated in these areas.

After film formation on a substrate is completed, cleaning inner walls of a reaction chamber is desirable. For example, cleaning of a wall surface of the reaction chamber can be performed by introducing oxygen (O₂) and/or a mixture gas of CₓF_{y} (x and y are any natural numbers respectively) and an inert gas into the reaction chamber and generating plasma between electrodes; after film formation on a substrate is completed, cleaning of a wall surface of the reaction chamber can be performed by introducing a gas containing radical molecules containing O and/or F into the reaction chamber; or after film formation on a substrate is completed, cleaning of a wall surface of the reaction chamber can be performed by introducing a gas containing radical molecules containing O and/or F into a reaction chamber, generating plasma between electrodes.

Additionally, after cleaning a wall surface of the reaction chamber is completed, by introducing a reducing gas and reducing radical molecules into the reaction chamber and generating plasma between electrodes, removing fluoride on the wall surface of the reaction chamber can also be performed. However, this regular in situ cleaning method is not sufficient to inhibit the accumulation of the unwanted deposits at the bottom surface of the chamber as well as completely remove these unwanted deposits. Accordingly, after numerous cycles more involved ex situ wet chemical cleaning is often employed, which involves significant downtime of the reactor.

To resolve this issue, an insulator (typically a ceramic material) as described about with respect to FIGS. 1 and 2 was located at the bottom surface of the chamber interior below the susceptor or heater top surface and adjacent to the bottom aluminum surface and surprising results were confirmed in Example 2 described below.

### EXAMPLE 2 AND COMPARATIVE EXAMPLE 2

The film formation and cleaning were continuously performed up to 500 cycles (500 wafers for the illustrated single wafer processing chambers) to study the amount of unwanted residue built up under the bottom surface of the chamber. The test was performed in the chamber with (Example 2) and without (Comparative Example 2) the ceramic material under the same deposition and regular in situ cleaning condition. A substrate, particularly a bare Si wafer with a size of approximately 4 cm×4 cm (a wafer chip) was located under the heater above the bottom surface of the reaction chamber near the exhausts port such that unwanted deposits can be built up on the wafer chip surface for a farther study on the quantity of accumulation and analysis of the accumulation.

Deposition conditions: Deposition conditions in the examples were as follows: Eagle®12 (ASM Japan) possessing a basic structure shown in FIGS. 1 and 2 was used as a reactor. Additionally, in the case of these examples, although a liquid monomer was flow-controlled by a flow control unit in a liquid phase, an amount of gas introduced into a reactor was obtained by molar conversion from the flow rate of the liquid.

### COMPARATIVE EXAMPLE 2

Reactor settings:

Temperature of upper electrode (shower plate): 180° C.

Size of shower plate: φ325 mm (Size of substrate: φ300 mm)

Susceptor temperature: 340° C.

Vaporizer: Vaporizing unit temperature: 40° C.

Controlled temperature of gas inlet piping: 100° C.

Gap between shower plate and susceptor: 16 mm

Process conditions:

Precursor: Cyclopentene: 200 sccm

He supplied to vaporizer: 500 sccm

Ar supplied to the reactor: 1700 sccm

Process gas He supplied to the reactor: 1300 sccm

RF Power (13.56 MHz): 2300 W

Pressure: 733 Pa

Deposition time: 18.5 sec

Deposited film properties:

Deposition Rate: 640 nm/min

Thickness: 200 nm

Reflective Index (n) @633 nm: 1.88

Extinction Coefficient (k) @633 nm: 0.09

Stress: −286 MPa

Accumulated film thickness: 20 nm

### EXAMPLE 2

Under the substantially same conditions as in Comparative Example 2 except that the ceramic material used in Example 1 was located at the bottom surface of the chamber interior below the heater top surface and adjacent to the bottom aluminum surface. An accumulated film thickness was evaluated in the same way as in Comparative Example 2.

Process conditions:

Precursor: Cyclopentene: 200 sccm

He supplied to vaporizer: 500 sccm

Ar supplied to the reactor: 1700 sccm

Process gas He supplied to the reactor: 1300 sccm

RF Power (13.56 MHz): 2300 W

Pressure: 733 Pa

Deposition time: 15.5 sec

Deposited film properties:

Deposition Rate: 790 nm/min

Thickness: 200 nm

Reflective Index (n) @633 nm: 1.88

Extinction Coefficient (k) @633 nm: 0.09

Stress: −288 MPa

Accumulated film thickness: <2 nm (Residues can not be identified from visual inspection). No unwanted residues were observed on the wafer chip.

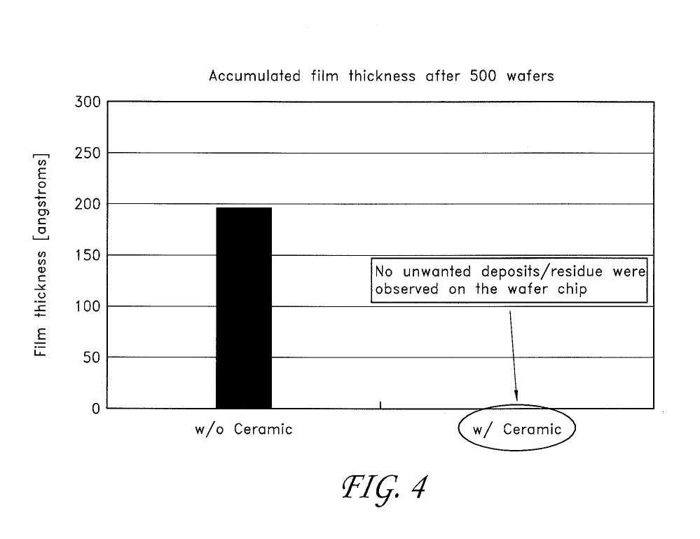

As compared with Comparative Example 2, when the ceramic material was located at the bottom surface of the chamber interior below the heater top surface and adjacent to the bottom aluminum surface, no unwanted residues were observed on the wafer chip which consequently shows that a tremendous improvement was achieved (see FIG. 4).

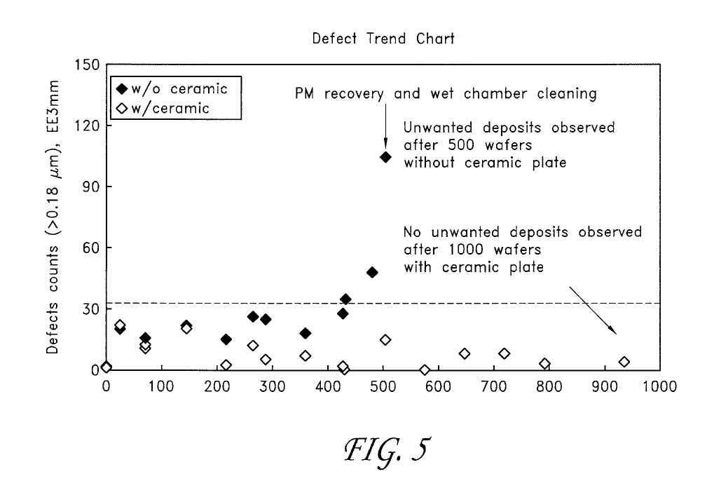

Furthermore, as can be seen from FIG. 5, the number of particles with the particle size of >0.18 μm generated while processing wafers remains relatively low as compared to that without the ceramic configuration. Surprisingly, the use of the ceramic plate enabled a run of more than 500 wafers, and in the example of FIG. 5 more than 1000 wafers, without any maintenance or periodic cleaning operation, other than the regular in situ cleanings. The periodic ex situ (typically wet chemical) cleaning operation is basically determined either when high particle generation is observed while processing the wafers or by visual inspection of residue build up through a view port. As a result, productivity per one hour was increased and the PM (Periodic Maintenance) cycle span was increased by more than 50%. Thus, the insulating member enables continuous processing of more than 500 wafers, and in the conducted experiments more than 1000 wafers, without intervening ex situ chamber cleaning.

In summary, the normal deposition of 200 nm of carbon-containing material per wafer, with regular in situ cleaning (“in situ cleaning” employs vapor phase cleaning agents such as etchants, whether through thermal reaction, in situ plasma and/or remote plasma), after 500 wafers (total of 100,000 nm deposited) left 20 nm of accumulated deposit on the chamber walls without the insulating member at the bottom of the chamber. In contrast, with the insulating member (ceramic insert), the same process produced less than 2 nm of accumulated deposit on the chamber walls. Moreover, deposition rates on the wafers improved with the insulating insert on the bottom reactor wall. Thus, reactor downtime for periodic maintenance, including ex situ chemical clean, can be reduced significantly, while deposition rates simultaneously increase, by means of the insulating member as disclosed here.

The present invention includes the above mentioned embodiments and other various embodiments including the following individually or in any combination:

1) A method of continuously forming carbon-based films (or carbon-containing films or carbonaceous films) on a substrate, comprising:

(i) forming a carbon-based film on a substrate in a reactor a determinable number of times;

(ii) exciting oxygen gas, nitrogen tri-fluoride gas, and an inert gas such as Ar to generate a plasma for cleaning;

(iii) cleaning an inside of the reactor with the plasma to remove particles accumulated during step (i) on the inside of the reactor.

2) The method according to item 1, wherein step (ii) is conducted in the reactor and/or a remote plasma unit.

3) The method according to item 1 or 2, wherein the inert gas is one or more types of gas.

4) The method according to item 3, wherein the inert gas is Ar and one or more types of other gas.

5) The method according to any one of items 1 to 4, wherein the oxygen gas is O₂ gas.

6) The method according to any one of items 1 to 5, wherein a flow rate of the oxygen gas is no less than 10 sccm and no more than 10,000 sccm.

7) The method according to item 6, wherein a flow rate of the oxygen gas is no less than 100 sccm and no more than 5,000 sccm.

8) The method according to any one of items 1 to 7, wherein a flow rate of the nitrogen tri-fluoride gas is no less than 1 sccm and no more than 5,000 sccm.

9) The method according to any one of items 1 to 8, wherein a flow rate of the nitrogen tri-fluoride gas is no less than 5 sccm and no more than 1,000 sccm.

10) The method according to any one of items 1 to 9, wherein a flow rate of the nitrogen tri-fluoride gas is no less than 10 sccm and no more than 500 sccm.

11) The method according to any one of items 1 to 10, wherein a susceptor on which the substrate is placed has a temperature of 200° C. or higher in steps (i) through (iii).

12) The method according to any one of items 1 through 10, further comprising determining a priority area of cleaning inside the reactor prior to step (ii).

13) The method according to item 11, wherein step (iii) comprises controlling pressure inside the reactor according to the priority area of cleaning.

14) The method according to item 11 or 12, wherein step (iii) comprises controlling pressure inside the reactor at about no control state (OPa) to about 400 Pa.

15) The method according to item 2, wherein step (ii) is conducted in the reactor.

16) The method according to any one of items 1-16, wherein the carbon-based polymer film in step (i) is a carbon polymer film formed by:

vaporizing a hydrocarbon-containing liquid monomer (C_{α}H_{β}X_{γ}, wherein α and β are natural numbers of 5 or more; γ is an integer including zero; X is O, N or F) having a boiling point of about 20° C. to about 350° C. which has no benzene structure;

introducing said vaporized gas into a CVD reaction chamber inside which a substrate is placed; and

forming a hydrocarbon-containing polymer film on said substrate by plasma polymerization of said gas.

17) A method of self-cleaning a plasma reactor using a cleaning gas containing oxygen gas, nitrogen tri-fluoride gas, and inert gas, comprising: (i) forming a carbon-based film on the substrate in the reactor a pre-selected number of times;

(ii) exciting oxygen gas, nitrogen tri-fluoride gas, and inert gas to generate a plasma for cleaning;

(iii) cleaning an inside of the reactor with the plasma to remove particles accumulated during step (i) on the inside of the reactor; and

(iv) repeating steps (i)-(iii) a pre-selected number of times.

18) The method according to item 17, wherein step (ii) is conducted in the reactor and/or a remote plasma unit.

19) A method of continuously forming films such as carbon-based films on substrates in a capacitively-coupled plasma CVD reactor, comprising:
(I) locating an insulator (typically a ceramic) at the bottom surface of the interior chamber below the heater surface and adjacent to the bottom surface,
(II) forming a film on a substrate in the reactor a determinable number of times;
(III) exciting oxygen gas, and nitrogen fluoride gas, and inert gas to generate a plasma for cleaning; and
(IV) cleaning an inside of the reactor with the plasma to remove particles accumulated during step (ID on the inside of the reactor.

20) The method according to any of the foregoing embodiments, wherein in step (I), the insulator is constituted by aluminum oxide.

21) The method according to any of the foregoing embodiments, wherein in step (I), the insulator is constituted by aluminum nitride.

22) The method according to any of the foregoing embodiments, wherein in step (I), the insulator is constituted by silicon oxide.

23) The method according to any of the foregoing embodiments, wherein in step (I), the insulator has a thickness of above 0.1 mm.

24) The method according to any of the foregoing embodiments, wherein in step (I), the insulator is positioned between the heater and the reactor bottom.

25) The method according to any of the foregoing embodiments, wherein in step (I), the insulator is positioned in contact with the bottom surface of the reactor.

26) The method according to any of the foregoing embodiments, wherein in step (I), the insulator is positioned between the heater and the reactor bottom in contact with the bottom surface having a contact portion of less than 50% of the area of the insulator, whereas the remaining area of the non-contact portion being spaced apart from the bottom surface.

27) The method according to any of the foregoing embodiments, wherein in step (I), the insulator is secured by screws to the reactor bottom surface.

28) A plasma chemical vapor deposition apparatus comprising: a reaction chamber; electrodes provided in the reaction chamber; and a bottom surface formed as a part of the reaction chamber and having its surface covered with a ceramic material where wafer supporting pins are secured and aligned by the ceramic material.

29) The method according to any of the foregoing embodiments, wherein the insulator in step (i) acts as an insulator/barrier for inhibiting the penetration of the magnetic field.

30) The method according to any of the foregoing embodiments, wherein the insulator in step (I) promotes in increasing the plasma potential between the upper electrode and the bottom electrode, which consequently results in less consumption of RF power during semiconductor wafer processing, leading to environmental benefits such as contribution to minimize greenhouse effect.

31) The method according to any of the foregoing embodiments, wherein step (III) may be conducted in the reactor or may be conducted in the reactor and in a remote plasma unit.

32) The method according to any of the foregoing embodiments, further comprising determining a priority area of cleaning inside the reactor prior to step (III).

33) The method according to embodiment 32, wherein step (IV) may comprise controlling pressure inside the reactor according to the priority area of cleaning.

34) The method according to any of the foregoing embodiments, wherein the film in step (II) is a carbon-based polymer film formed by:

vaporizing a hydrocarbon-containing liquid monomer (C_{α}H_{β}X_{γ}, wherein α and β are natural numbers of 5 or more; γ is an integer including zero; X is O, N or F) having a boiling point of about 20° C. to about 350° C. which is not substituted by a vinyl group or an acetylene group;

introducing said vaporized gas into a CVD reaction chamber inside which a substrate is placed; and

forming a hydrocarbon-containing polymer film on said substrate by plasma polymerization of said gas.

35) A method of self-cleaning a plasma reactor using a cleaning gas containing oxygen gas, nitrogen tri-fluoride gas, and inert gas, comprising:

(a) forming a carbon-based film on the substrate in the reactor a pre-selected number of times;

(b) exciting oxygen gas, nitrogen tri-fluoride gas, and inert gas to generate a plasma for cleaning;(c) cleaning an inside of the reactor with the plasma to remove particles accumulated during step (a) on the inside of the reactor; and

(d) repeating steps (a)-(c) a determinable number of times.

36) The method according to any of the foregoing embodiments, wherein step (b) is conducted in the reactor and/or a remote plasma unit.

37) The method according to any of the foregoing embodiments, wherein in step (b), an inert gas is added in an amount greater than the oxygen gas.

38) The method according to any of the foregoing embodiments, wherein the fluorine-containing gas is constituted solely by nitrogen tri-fluoride.

39) The method according to any of the foregoing embodiments, wherein the oxygen-containing gas is constituted solely by oxygen.

40) The method according to any of the foregoing embodiments, wherein in step (b), argon is added in an amount greater than the oxygen gas.

41) A method of continuously forming carbon-based films on substrates, comprising:

(A) forming a carbon-based film on a substrate in a reactor a pre-selected number of times;

(B) exciting a cleaning gas comprised of an oxygen-containing gas and a fluorine-containing gas to generate a plasma for cleaning, wherein the cleaning gas contains the fluorine-containing gas in an amount effective to increase a cleaning rate as compared with a cleaning rate obtained without the fluorine-containing gas; and

(C) cleaning an inside of the reactor with the plasma after step (A) to remove particles accumulated during step (A) on the inside of the reactor.

It will be understood by those of skill in the art that numerous and various modifications can be made without departing from the spirit of the present invention. Therefore, it should be clearly understood that the forms of the present invention are illustrative only and are not intended to limit the scope of the present invention.

What is claimed is:

1. A plasma CVD apparatus for forming a film on a substrate comprising:
an evacuatable reaction chamber;
capacitively-coupled upper and lower electrodes disposed inside the reaction chamber, wherein a substrate is to be placed on the lower electrode, said reaction chamber having a conductive bottom surface above which the lower electrode is installed; and
an insulator for inhibiting penetration of a magnetic field of radio frequency (RF) generated during substrate processing, said insulator being placed on the bottom surface of the reaction chamber under the lower electrode.

2. The plasma CVD apparatus according to claim 1, wherein the insulator is made of a ceramic material.

3. The plasma CVD apparatus according to claim 2, wherein the ceramic material is selected from the group consisting of aluminum oxide, aluminum nitride, silicon oxide, and silicon carbide.

4. The plasma CVD apparatus according to claim 1, wherein the lower electrode is supported at its center by a support, and the bottom surface of the reaction chamber has a hole through which the support is installed, wherein the insulator has a ring shape having a hole corresponding to the hole of the bottom surface.

5. The plasma CVD apparatus according to claim 1, wherein the insulator has a diameter larger than that of the lower electrode.

6. The plasma CVD apparatus according to claim 1, wherein the insulator is mechanically replaceable.

7. The plasma CVD apparatus according to claim 6, wherein the insulator is fastened to the bottom surface with screws.

8. The plasma CVD apparatus according to claim 1, wherein the upper electrode is a showerhead, and the lower electrode is a susceptor.

9. The plasma CVD apparatus according to claim 1, wherein the insulator has a shape and size corresponding to a shape and size of the bottom surface.

10. The plasma CVD apparatus according to claim 1, wherein the insulator has a thickness greater than a distance between the upper and lower electrodes set for plasma processing.

11. The method according to claim 1, wherein the insulator has a thickness of at least 5 mm.

12. The plasma CVD apparatus according to claim 1, wherein the reaction chamber is separated into two portions composed of a reaction region and a substrate transferring region, between which the lower electrode moves.

13. A method for improving production throughput in a plasma CVD apparatus comprising: an evacuatable reaction chamber; capacitively-coupled upper and lower electrodes disposed inside the reaction chamber; and an electrical insulator placed on the bottom surface of the reaction chamber under the lower electrode, said method comprising:
installing an insulator for inhibiting penetration of a magnetic field of radio frequency (RF) generated during substrate processing, under the lower electrode and on a conductive bottom surface of the reaction chamber; and
depositing a film on a substrate placed on the lower electrode by plasma CVD applying RF power between the upper and lower electrodes, wherein as a result of the installed insulator, a deposition rate is increased and unwanted deposition inside the reaction chamber is reduced.

14. The method according to claim 13, wherein the insulator is made of a ceramic material.

15. The method according to claim 13, wherein the deposition rate is increased by at least 10% as compared with that without the insulator.

16. The method according to claim 13, further comprising cleaning the reaction chamber, wherein a frequency of chamber cleaning is reduced as a result of the installed insulator.

17. The method according to claim 16, wherein the frequency of chamber cleaning is reduced by at least 50% as compared with that without the insulator.

18. The method according to claim 16, wherein the cleaning is conducted using a fluorine-containing gas.

19. The method according to claim 13, wherein the film is a carbon-based film.
